(19) United States
(12) Patent Application Publication
(10) Pub. No.: US 2004/0028151 A1
(43) Pub. Date: Feb. 12, 2004

(54) Conversion circuit, tuner and demodulator

(76) Inventors: Bernard Arambepola, London (GB); Philip Hackney, Swindon (GB)

Correspondence Address: Mark D. Saralino, Renner, Otto, Boisselle & Sklar, LLP, Nineteenth Floor, 1621 Euclid Avenue, Cleveland, OH, 44115-2191, US

(21) Appl. No.: 10/635,782

(22) Filed: Aug. 6, 2003

(30) Foreign Application Priority Data
Aug. 7, 2002 (GB) 0218298.8

(51) Int. Cl. H03K 9/00; H04L 27/06

(52) U.S. Cl. 375/316

(57) ABSTRACT

In-phase and quadrature baseband analog signals are supplied from a tuner front end to respective sample and hold circuits which sample their input signals at different times. The resulting samples are converted by a single ADC and the I or Q digital samples are supplied to an interpolator. The interpolator performs interpolation on, for example, the Q digital samples to obtain further samples at the same sampling points as the I signal. The resulting samples are supplied to a digital demodulator.

### FIELD

The present invention relates to a conversion circuit for converting analog baseband in-phase and quadrature signals to digital signals. The present invention also relates to radio frequency tuners and demodulators including such a conversion circuit.

### BACKGROUND

It is known to provide a radio receiver, for example for orthogonal frequency division multiplexed (OFDM) signals, for example for digital terrestrial television reception. As part of the demodulation function of signals of this and other types, in-phase and quadrature signals are generated. In known arrangements, the selected channel for reception is converted to a sufficiently low intermediate frequency or to baseband and the resulting composite signal is then supplied to an analog-digital converter (ADC), which samples and digitises the input signal to provide a digital composite signal. Separation of the in-phase and quadrature components is then performed in the digital domain.

There are advantages to deriving the in-phase and quadrature components in the analog domain before digitisation in an ADC. In such an arrangement, the quadrature conversion is performed by the radio frequency circuitry and results in analog baseband in-phase and quadrature signals or signal components, which then have to be converted to the digital domain. An example of this type of arrangement is shown in FIG. 1 of the accompanying drawings. A broadband radio frequency (RF) signal, for example from a terrestrial aerial, a satellite aerial system or a cable distribution system, is received at an input 1 of a tuner and is supplied to in-phase and quadrature mixers 2 and 3. A local oscillator (OSC) 4 supplies a local oscillator signal directly to the mixer 2 and via a 90° phase shifter 5 to the mixer 3. The oscillator 4 is tunable over a sufficiently wide range of frequencies to be able to select any desired channel from the broadband input signal for reception.

The mixers 2 and 3 convert the selected channel to baseband in-phase and quadrature components, which are supplied to anti-aliasing low pass filters (LPF) 6 and 7, which filter the in-phase and quadrature signals before supplying them to respective ADCs 8 and 9, respectively. In order for the following digital demodulation processing to be performed, the ADCs 8 and 9 sample the in-phase and quadrature signals at the same time instants.

Although a circuit arrangement of the type illustrated in FIG. 1 provides an acceptable performance, it requires two ADCs. Fast ADCs occupy a substantial amount of silicon area in an integrated circuit and consume a relatively large amount of power, which makes such an arrangement disadvantageous because of cost and power consumption.

### SUMMARY

According to a first aspect of the invention, there is provided a conversion circuit for converting analog baseband in-phase and quadrature signals to digital signals, comprising: a first sampling circuit for sampling one of the analog in-phase and quadrature signals at a first series of first times to provide first samples; a second sampling circuit for sampling the other of the analog in-phase and quadrature signals at a second series of second times different from the first times to provide second samples; a single analog-digital converter for converting the first and second samples to first and second digital samples; and an interpolator for interpolating at least one of the first and second digital samples to produce first and second output digital samples representing the one and the other, respectively, of the analog in-phase and quadrature signals at third and fourth series of third and fourth times, respectively, with the difference between each third time and the respective fourth time being less than the difference between the corresponding first and second times.

The difference between each third time and the respective fourth time may be substantially zero.

The interpolator may be arranged to interpolate only the second digital samples.

The circuit may comprise a delaying circuit for delaying the first digital samples by a time delay substantially equal to the latency of the interpolator.

Each of the second times may be between the first times of a consecutive pair. Each of the second times may be half way between the first times of the consecutive pair.

The interpolator may be arranged to perform band-limited interpolation. The interpolation may be a windowed sinc interpolation. The window may be a Hamming window. As an alternative, the interpolation may be a spline interpolation.

The interpolator may be arranged to control the difference between each third time and the respective fourth time in accordance with a feedback signal representing a quality of reception. The reception quality may be at least one of signal-to-noise ratio and bit-error-rate.

The circuit may be formed as a single monolithic integrated circuit.

According to a second aspect of the invention, there is provided a radio frequency tuner comprising a circuit according to the first aspect of the invention and a frequency converter for converting a selected radio frequency channel to the analog baseband in-phase and quadrature signal.

The tuner may comprise a digital demodulator arranged to receive the first and third digital samples.

According to a third aspect of the invention, there is provided a demodulator comprising a circuit according to the first aspect of the invention and a demodulating arrangement arranged to receive the first and third digital samples.

It is thus possible to provide an arrangement which converts analog baseband in-phase and quadrature signals to digital samples requiring only a single ADC. This results in a substantial saving of silicon area on an integrated circuit and minimises or reduces power consumption compared with other techniques. Such an arrangement makes available in-phase and quadrature digital samples effectively sampled at the same times to allow subsequent processing in the digital domain and allows the standard techniques to be used for retrieving the modulating signals.

### BRIEF DESCRIPTION OF DRAWINGS

FIG. 1 illustrates schematically a possible architecture for a radio frequency tuner;

FIG. 2 is a block schematic diagram of an analog-digital conversion arrangement given by way of a comparative example;

FIG. 3 is a timing diagram relating to the arrangement of FIG. 2;

FIG. 4 is a block schematic diagram of another analog digital conversion arrangement given as a comparative example;

FIG. 5 is a timing diagram for the arrangement of FIG. 4;

FIG. 6 illustrates the sampling process performed by the arrangement of FIG. 4;

FIG. 7 illustrates the frequency spectra in the complex plane of a received radio frequency channel, a baseband modulating signal to be recovered, and baseband in-phase and quadrature components;

FIG. 8 illustrates the frequency spectra of sampled baseband signals and components;

FIG. 9 illustrates a sampling process on in-phase and quadrature components;

FIG. 10 is a block schematic diagram of part of a conversion circuit constituting an embodiment of the invention;

FIG. 11 illustrates a variation of the timing diagram of FIG. 5;

FIG. 12 is a block schematic diagram of a tuner and demodulator incorporating a conversion circuit including the part illustrated in FIG. 10 and constituting an embodiment of the invention; and

FIG. 13 is a diagram similar to FIG. 12 illustrating another embodiment of the invention.

Like reference numerals refer to like parts throughout the drawings.

### DETAILED DESCRIPTION

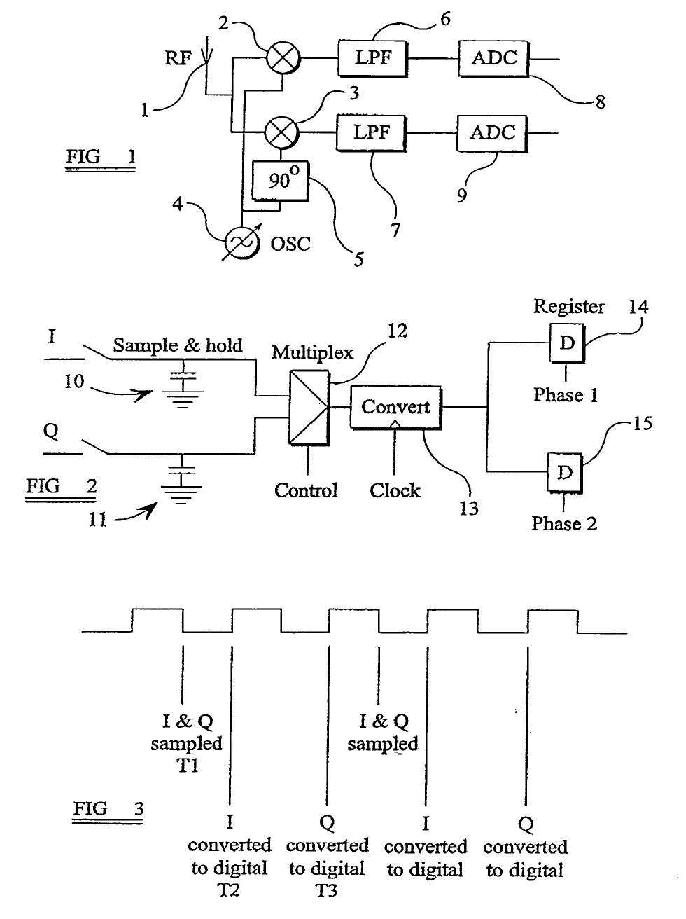

FIG. 2 illustrates one possible example of providing conversion of analog baseband in-phase and quadrature signals to digital signals using a single analog-digital converter. The in-phase (I) and quadrature (Q) signals from a tuner arrangement are supplied to sample and hold circuits 10 and 11 illustrated schematically as series switches and storage capacitors. The outputs of the circuits 10 and 11 are supplied to respective inputs of a multiplexer 12 whose output is supplied to an ADC 13. The output of the ADC 13 is supplied to clocked delay circuits or registers 14 and 15, which act as a demultiplexer for separating the in-phase and quadrature digital samples from the converter 13.

The control and clock signals supplied to the various parts of the circuit of FIG. 2 are illustrated with reference to a system clock signal shown in FIG. 3. In order for the I and Q signals to be sampled at the same times, control signals are supplied to the sample and hold circuits 10 and 11 at the time instant T1. At a time instant T2, a control signal is supplied to the multiplexer 12, which passes the I sample to the converter 13. The converter 13 performs analog-digital conversion and the digitised I sample is then clocked into the register 14.

At time T3, the multiplexer 12 supplies the Q sample to the converter 13 which converts it to a digital sample and clocks this into the register 15.

In such an arrangement, the I and Q samples are converted to digital samples with different time delays. This affects the accuracy of the analog-digital conversion process, which is limited by both the resulting total harmonic distortion (THD) and the signal-to-noise ratio (SNR).

Practical sample and hold circuits such as 10 and 11 have a finite output settling response which presents a harmonic distortion limitation to the conversion process which is dependent on the available settling time. In the example illustrated in FIGS. 2 and 3, the settling time available for the I sample is half a clock period whereas the settling time available for the Q samples is three half clock periods and this results in a harmonic distortion mismatch between the channels. To ensure that such a mismatch would be negligible, the sample and hold circuits 10 and 11 would need to meet a specified accuracy when operating with a maximum settling time of half a clock period.

The SNR of the analog-digital conversion may also differ between the two channels. For example, where the sample and bold circuits 10 and 11 and the ADC 13 are connected to finite impedance power and ground supplies, which also supply logic circuitry synchronised to a master clock signal of half the ADC sampling rate, a damped oscillation is produced on the power and ground nodes of the circuits. Practical circuits have only a limited degree of power supply rejection and, because the amplitude of supply oscillations may be significantly less for the Q channel than for the I channel, differences in SNR can result. This creates problems because accuracy of analog-digital conversion is very important in order to obtain high performance from digital signal processing systems.

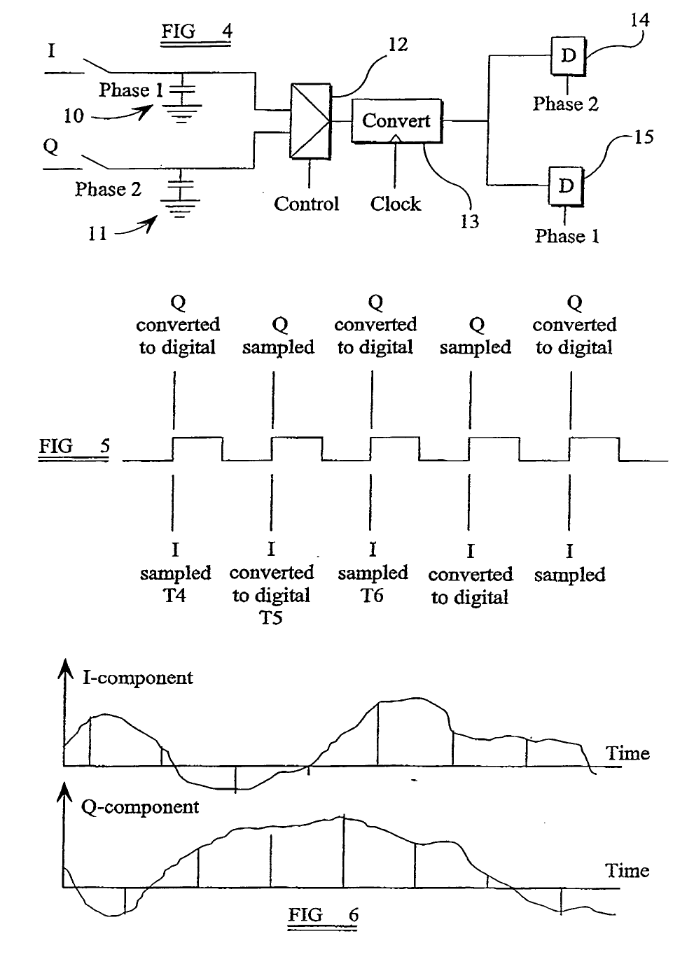

FIGS. 4 and 5 illustrate an alternative arrangement in which the I and Q signals are not sampled at the same times. Thus, differently phased control signals (phase 1 and phase 2) are supplied to the sample and hold circuits. As shown in FIG. 5, at time T4, the I signal is sampled. At time T5, the I sample is converted to a digital sample and the Q signal is sampled. At time T6, the Q sample is converted to a digital sample and the I signal is again sampled, and so on.

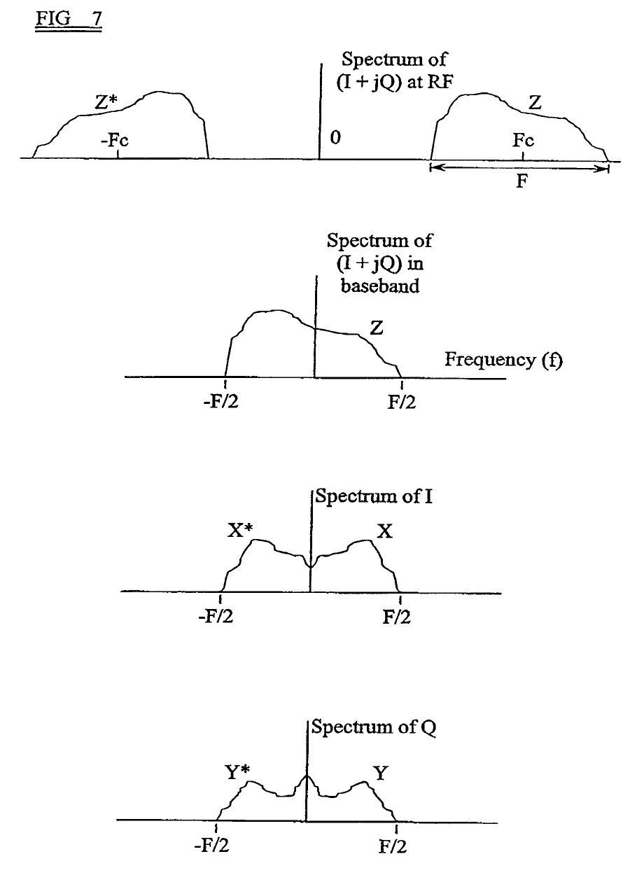

A settling time of one clock cycle is thus provided for each of the I and Q channels. This increase in settling time for the circuits 10 and 11 reduces the design requirements and the power dissipation and provides high performance analog-digital conversion. However, the I and Q components are sampled at different times as illustrated in FIG. 6 and the resulting digital samples are not suitable for subsequent digital signal processing.

The top diagram in FIG. 7 illustrates the spectrum of the selected channel or signal at radio frequency with a carrier frequency Fc and a bandwidth F. The next diagram illustrates the signal after conversion to baseband and after low pass filtering to prevent aliasing in subsequent signal processing steps. The next two diagrams illustrate the individual spectra for the I and Q components.

Although the spectrum of the baseband (I+jQ) signal is generally asymmetric, the spectra of the individual I and Q components exhibit conjugate symmetry about zero frequency. In other words, X(f)=X*(−f) and Y(f)=Y*(−f).

The spectra resulting from sampling the baseband signal at a frequency F are illustrated in FIG. 8 and the individual spectra are repeated with a period F. However, because the signals I and Q are not sampled at the same times, the expected relationships given by the following equations do not apply:

Z(f)=X(f)+jY(f) for f≧0 and Z(f)=X*(f)+jY*(f) for f<0

Where the * refers to the complex conjugate.

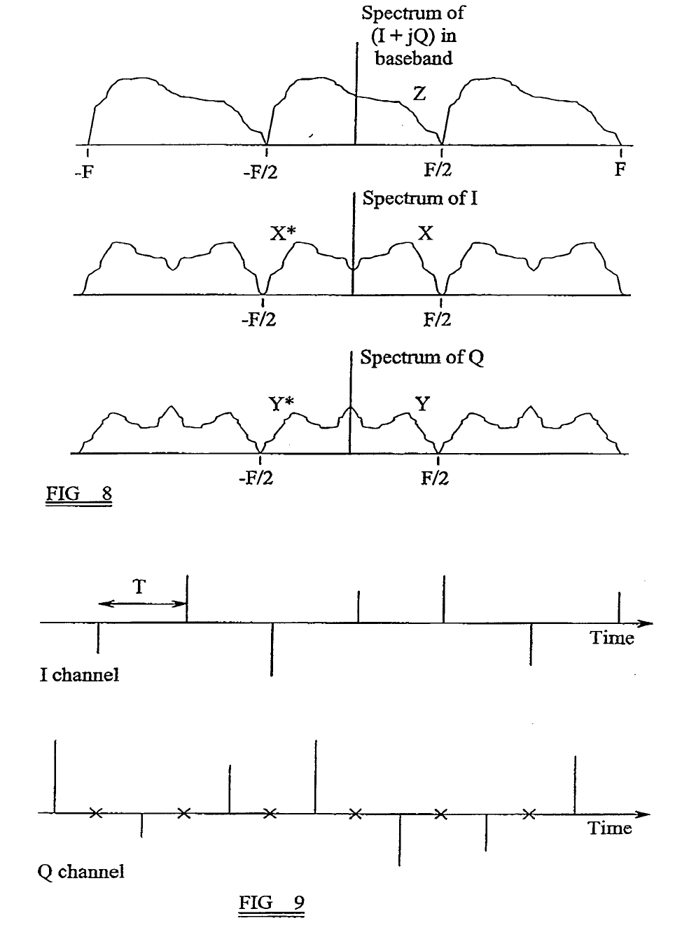

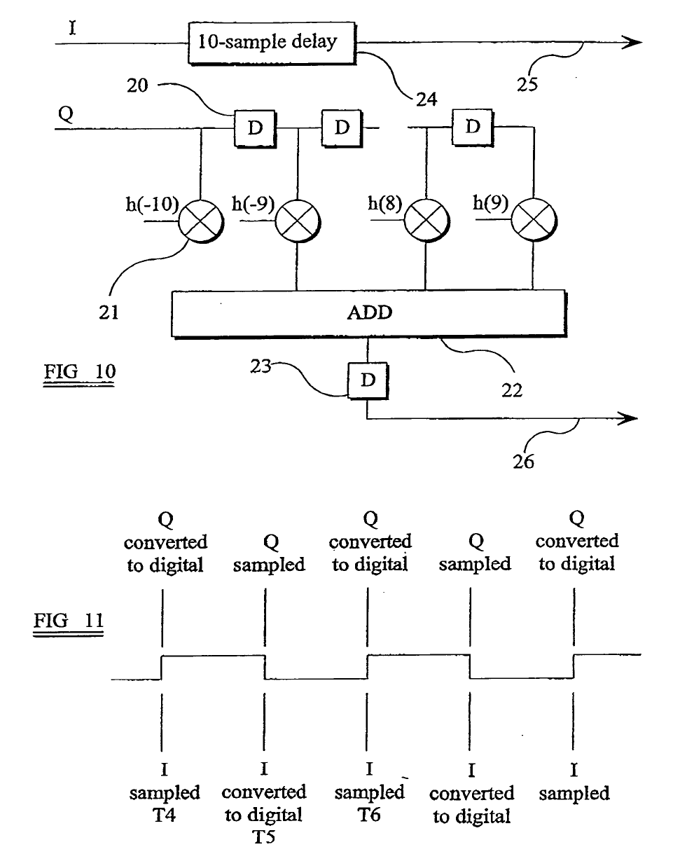

As illustrated in FIG. 7, the I or “real” part and the Q or “imaginary” part of the complex baseband signal are both real-valued signals with a maximum frequency of F/2. For the sampling frequency of F, both parts satisfy the Nyquist criterion for real valued signals as illustrated in FIG. 8. Thus, either of these signals can be interpolated independently to obtain any intermediate value of the corresponding analog signal illustrated in FIG. 6. In other words, any point of the analog signal I or Q can be reconstructed by digitally interpolating the sampled values of the corresponding signal. As illustrated in FIG. 9, the Q signal can be interpolated to obtain the values at the sampling times of the I signal, where the sampling period T is equal to 1/F.

For example, the sample-sequence of the quadrature (Q) channel can be interpolated to obtain the values of the corresponding analog channel Q at time instants mid-way between sampling instants.

Any known interpolation technique can be used for this purpose. The best known method for band-limited interpolation makes use of the sinc function sin (πx)/πx. This is a very long function in time and hence a windowed version of this function given by the following equation is used:

$$h ( i ) = W ( i ) \frac{sin ( π ( i + 0.5 ) )}{π ( i + 0.5 )} , for i = 0 , 1 , … , N / 2 - 1 \qquad ( 1 )$$

where W is the window function. In this example, a Hamming window is chosen and the equation for this is:

W(i)=0.54−0.46 cos(2π(i+N/2)/(N−1)), for i=0,1, . . . ,N/2−1 (2)

However, there are other window functions which may be used for gradually tapering the “tail” of the sinc function to zero.

The interpolation function is symmetric about the centre and hence

h(i)=h(−i−1) (3)

The asymmetry in the index is because h(−1)=h(0).

The interpolated value at a specific time point is obtained by the weighted addition of N samples, N/2 to the left of the point and N/2 to the right, as shown by the following equation. The weighting function is h(i).

$$y ( k - 0.5 ) = {\sum }_{i = - N / 2}^{N / 2 - 1} h ( i ) y ( k + i ) \qquad ( 4 )$$

This interpolation operation is not perfect. There will be errors in interpolation, which can be decreased by increasing the value of N. In a digital hardware implementation, further errors will be caused by the need to quantise the weighting function coefficients to the finite wordlengths. These errors may be treated as a white noise process. The wordlengths and the interpolation length N have to be chosen such that the noise floor of the interpolation process is well below the thermal noise floor of the signals I and Q.

In terrestrial demodulation, the operating signal to noise ratio (SNR) is expected to be about 20 dB. With very high coding rates (to transmit maximum amount of data) the SNR may have to be increased to about 30 dB. Hence, as a design parameter, the SNR of the interpolation may be made equal to 45 dB. The interpolation noise floor is 25 dB below the typical input noise floor. In this case, the degradation of SNR due to interpolation is negligible. If the input SNR is 30 dB, then the interpolation noise floor is 15 dB below the input noise floor and the SNR degradation due to interpolation is about 0.13 dB. A 45 dB interpolation SNR can be achieved using an interpolation length N of 20 and a coefficient wordlength of 10 bits.

Satellite receivers operate with much poorer SNRs, usually below 10 dB. Hence the same interpolator can be used in a satellite demodulation application with negligible loss of performance. In fact, for such an application, the interpolation length could be substantially reduced without affecting performance.

IN QAM64 cable systems, the operating SNR is below 30 dB and hence this interpolator is adequate. In QAM256 cable systems, the operating SNR could be around 35 dB. Then this interpolator would degrade the SNR by about 0.5 dB, which may be unacceptable so that longer interpolators and larger wordlengths might be necessary.

FIG. 10 illustrates diagrammatically an interpolator of this type for receiving the demultiplexed I and Q digital samples from the ADC. In this case, interpolation is performed on the Q samples but it could equally well be performed on the I samples. In fact, interpolation could be used for both sets of samples such that the resulting digital samples represent the I and Q components at common sampling times.

The interpolator comprises a set of cascade-connected registers, such as 20, arranged to form a shift register such that each sample is delayed by one timing period by each register 20. The undelayed Q samples and the samples from the registers 20 are supplied via multipliers such as 21 to an adding or summing circuit 22. Each of the multipliers 21 multiplies the input sample by a corresponding term of the interpolation function h(i). The output of the adding circuit 22 is supplied via a further delay register 23 to provide the interpolated samples of the Q signal.

The I samples are supplied to a ten sample delay circuit 24, for example in the form of a shift register, providing a delay substantially equal to the latency of the interpolator. This latency may be more than ten samples, for example if pipelining operations are performed in the multiplers 21 and the summing circuit 22. In such a case, the circuit 24 provides additional sample delays to compensate for the additional latency. As a result, I and Q digital samples corresponding to the same sampling time are available, simultaneously at the outputs 25 and 26, respectively.

FIG. 10 illustrates a hardware implementation of the interpolator but it is also possible for such an arrangement to be implemented in software. Also, FIG. 10 illustrates one possible architecture for a hardware interpolator. Other architectures and implementations are possible. For example, another implementation may be derived from that shown in FIG. 10 by time-multiplexing a hardware multiplier between several multiplications if the multiplier speed is sufficiently greater than the sampling rate. It is also possible to exploit the symmetry of the interpolator to halve the number of multiplications by adding the Q samples with the same coefficients prior to multiplications.

In the case of hardware implementations, the interpolator occupies a much smaller area of silicon on an integrated circuit and has a much smaller power consumption than a second ADC would require. Also, the interpolator may be disposed in the same region of the integrated circuit as other digital logic circuitry with associated noisy clocks and power supplies and does not therefore require the provision of high quality power supplies and clock signals. A substantial saving in silicon area, power consumption and design complexity can therefore be achieved compared with alternative techniques.

In the arrangement shown in FIG. 10, only the Q samples are interpolated so as to represent analog Q values at the I sampling times. However, in general, the arrangement is symmetrical so that the Q samples may be un-interpolated and the I samples may instead be interpolated to values at the Q sampling times. Also, it is possible for both the I and the Q samples to be interpolated to values of the analog signals at times other than the I and Q sampling times.

FIG. 11 illustrates an alternative arrangement which resembles the timing illustrated in FIG. 5 but in which the clock frequency is halved and the sampling and conversion processes make use of the rising and falling edges of the clock signal. In this case, the mark-to-space ratio of the clock signal may not be exactly 50:50; for example, it might be 60:40. The same interpolation technique may be used except that the interpolation points will not be precisely at the centres of the sampling intervals. This may be accommodated by changing the interpolation coefficients in equation (1). For example, for a 60:40 mark-to-space ratio, the interpolation function is given by:

$$h ( i ) = W ( i ) \frac{sin ( π ( i + 0.6 ) )}{π ( i + 0.6 )} , for i = - N / 2 , … , 0 , 1 , … , N / 2 - 1 \qquad ( 5 )$$

In this case, the interpolation weight sequence is no longer symmetric about the centre point.

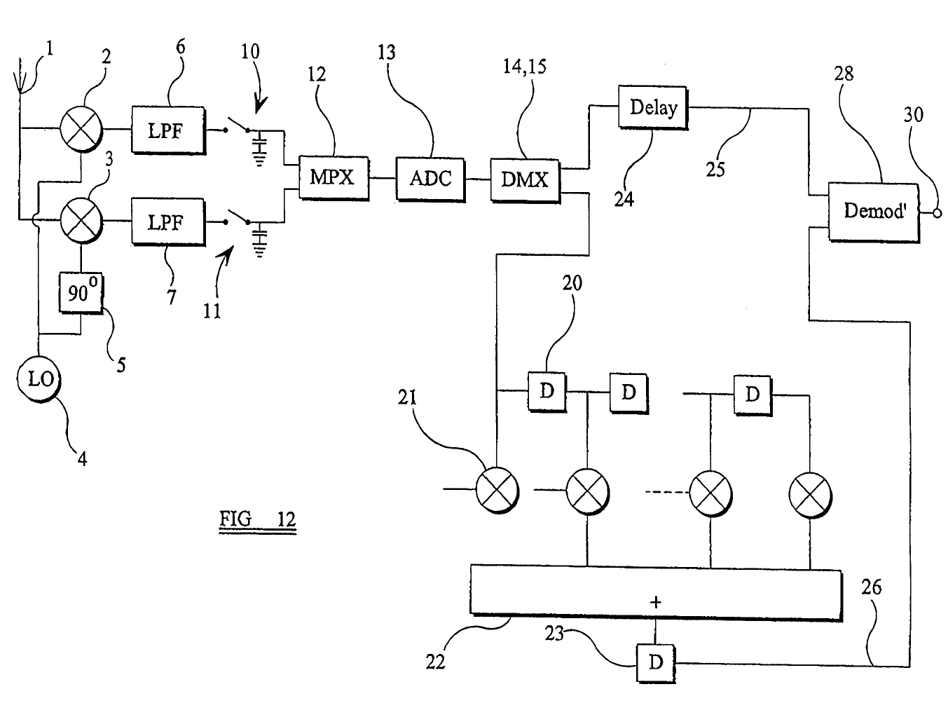

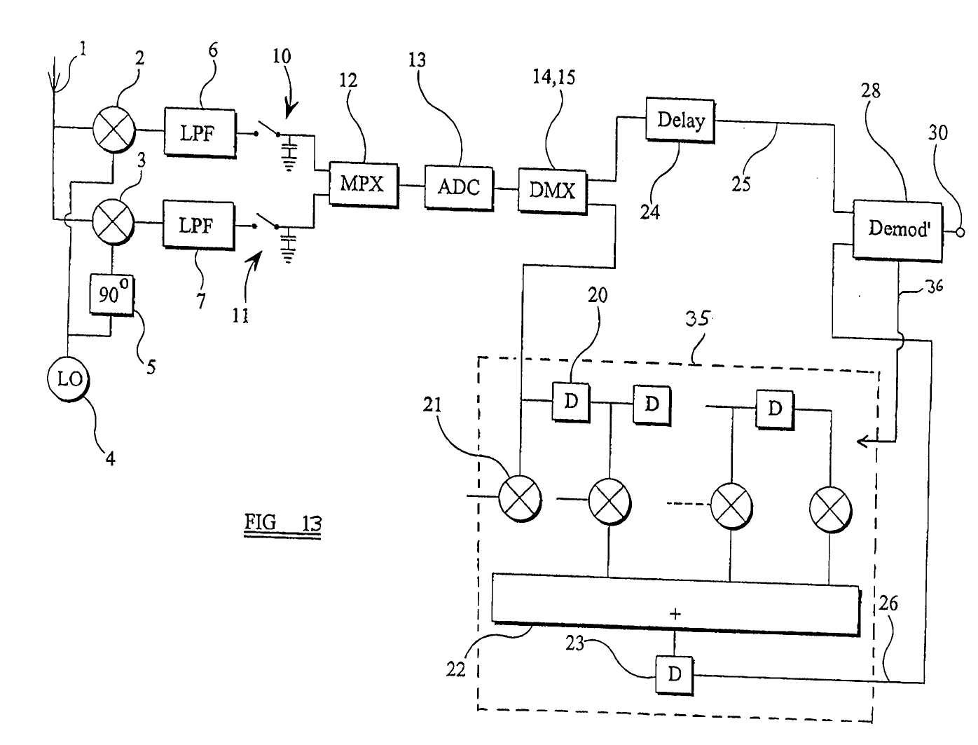

FIG. 12 illustrates a receiver comprising the conversion circuit 10-15, 20-26 as illustrated in FIGS. 4 and 10 together with a demodulator 28 for processing the I and Q samples at the outputs 25 and 26 in order to extract a demodulated signal and supply this to an output 30. Any suitable demodulating arrangement may be used in accordance with the modulation standard of the signal being received. The receiver further comprises a front end tuner arrangement of the type illustrated in FIG. 1 but omitting the individual ADCs 8 and 9, whose function is performed by the conversion circuit. Part or the whole of the receiver shown in FIG. 12 may be embodied as a single monolithic integrated circuit.

FIG. 13 illustrates a receiver which differs from that shown in FIG. 12 in that the interpolator 35 receives a control signal 36 from the demodulator 28 for controlling the interpolation phase. Thus, the timing points at which samples are interpolated is controlled in accordance with a quality of reception signal produced by the demodulator 28. For example, the demodulator 28 may produce one or more of; a differential timing error between I and Q channels; an estimate of the signal-to-noise ratio; a bit-error-rate signal. The signal 36 may be derived from one or more of these measures of reception quality and is used as a feedback signal to control the interpolation phase of the interpolator 35. Alternatively, the signal 36 may represent the difference between an actual reception quality signal and an acceptable threshold value for such a signal.

In accordance with the value of the signal 36 fed back from the demodulator 28, the interpolator 35 varies the times of the interpolated samples until the reception quality is maximised or is greater than an acceptable threshold level. This results in the sampling times of the interpolated samples being closer to the actual sampling times of the uninterpolated samples. Where the feedback is used to maximise reception quality, the interpolated samples will be interpolated at or close to the times of the uninterpolated samples. Where an acceptable quality of reception is achieved without necessarily optimising or maximising the reception quality, the interpolated samples will not generally coincide with the uninterpolated samples but will be much closer in time than would be achieved without interpolation.

What is claimed is:

1. A conversion circuit for converting analog baseband in-phase and quadrature signals to digital signals, comprising: a first sampling circuit for sampling one of said analog in-phase and quadrature signals at a first series of first times to provide first samples; a second sampling circuit for sampling another of said analog in-phase and quadrature signals at a second series of second times, different from said first times, to provide second samples; a single analog-digital converter for converting said first and second samples to first and second digital samples; and an interpolator for interpolating at least one of said first and second digital samples to produce first and second output digital samples representing said one and said other, respectively, of said analog in-phase and quadrature signals at third and fourth series of third and fourth times, respectively, with a difference between each said third time and a respective one of said fourth times being less than a difference between corresponding ones of said first and second times.

2. A circuit as claimed in claim 1, in which said difference between each said third time and said respective fourth time is substantially zero.

3. A circuit as claimed in claim 1, in which said interpolator is arranged to interpolate only said second digital samples to produce third digital samples representing said other of said analog in-phase and quadrature signals at said first times.

4. A circuit as claimed in claim 3, comprising a delaying circuit for delaying said first digital samples by a time delay substantially equal to a latency of said interpolator.

5. A circuit as claimed in claim 1, in which each of said second times is between said first times of a consecutive pair.

6. A circuit as claimed in claim 5, in which each of said second times is halfway between said first times of said consecutive pair.

7. A circuit as claimed in claim 1, in which said interpolator is arranged to perform band-limited interpolation.

8. A circuit as claimed in claim 7, in which said interpolation is a windowed sinc interpolation.

9. A circuit as claimed in claim 8, in which said window is a Hamming window.

10. A circuit as claimed in claim 7, in which said interpolation is a spline interpolation.

11. A circuit as claimed in claim 1, in which said interpolator is arranged to control said difference between each said third time and said respective fourth time in accordance with a feedback signal representing a quality of reception.

12. A circuit as claimed in claim 11, in which said reception quality is at least one of signal-to-noise ratio and bit-error-rate.

13. A circuit as claimed in claim 1, formed as a single monolithic integrated circuit.

14. A radio frequency tuner comprising a conversion circuit for converting analog baseband in-phase and quadrature signals to digital signals, comprising: a first sampling circuit for sampling one of said analog in-phase and quadrature signals at a first series of first times to provide first samples; a second sampling circuit for sampling another of said analog in-phase and quadrature signals at a second series of second times, different from said first times, to provide second samples; a single analog-digital converter for converting said first and second samples to first and second digital samples; and an interpolator for interpolating at least one of said first and second digital samples to produce first and second output digital samples representing said one and said other, respectively, of said analog in-phase and quadrature signals at third and fourth series of third and fourth times, respectively, with a difference between each said third time and a respective one of said fourth times being less than a difference between corresponding ones of said first and second times, and a frequency converter for converting a selected radio frequency channel to said analog baseband in-phase and quadrature signals.

15. A tuner as claimed in claim 14, comprising a digital demodulator arranged to receive said output digital samples.

16. A demodulator comprising a conversion circuit for converting analog baseband in-phase and quadrature signals to digital signals, comprising: a first sampling circuit for sampling one of said analog in-phase and quadrature signals at a first series of first times to provide first samples; a second sampling circuit for sampling another of said analog in-phase and quadrature signals at a second series of second times, different from said first times, to provide second samples; a single analog-digital converter for converting said first and second samples to first and second digital samples; and an interpolator for interpolating at least one of said first and second digital samples to produce first and second output digital samples representing said one and said other, respectively, of said analog in-phase and quadrature signals at third and fourth series of third and fourth times, respectively, with a difference between each said third time and a respective one of said fourth times being less than a difference between corresponding ones of said first and second times, and a demodulating arrangement arranged to receive said output digital samples.
